(19) United States
(12) Patent Application Publication
(10) Pub. No.: US 2026/0247714 A1
(43) Pub. Date: Aug. 20, 2026

(54) DISPLAY SUBSTRATE AND DISPLAY PANEL

(71) Applicants: Nanjing BOE Display Technology CO.,LTD., Nanjing,Jiangsu (CN); BOE TECHNOLOGY GROUP CO., LTD., Beijing (CN); Beijing BOE Technology Development Co., Ltd., Beijing (CN)

(72) Inventors: Jiayi FANG, Beijing (CN); Wei YANG, Beijing (CN); Qin ZHANG, Beijing (CN); Yanlong LI, Beijing (CN); Wei GAO, Beijing (CN); Xianjie SHAO, Beijing (CN)

(21) Appl. No.: 18/995,245

(22) PCT Filed: May 15, 2024
(86) PCT No.: PCT/CN2024/093350

§ 371 Date: Jan. 16, 2025

(30) Foreign Application Priority Data
Jun. 29, 2023 (CN) 202310783705.4

(51) Int. Cl. H10D 86/40

(52) U.S. Cl. CPC H10D 86/441; H10D 86/423

(57) ABSTRACT

Embodiments of the present disclosure provide a display substrate and a display panel. The display substrate includes a base substrate, with a display region and a peripheral region surrounding display region thereon. The display substrate includes a plurality of thin film transistors each including a gate electrode and an active pattern, the active pattern include a first connection part, a second connection part and a channel part connected between the first and second connection parts, and the channel part and the gate electrode are opposite to and insulated from each other. The gate electrode of the thin film transistor is on a side of the active pattern away from the base substrate, and a Hall mobility of the active pattern of the thin film transistor is greater than or equal to 20 cm²/V·s. The display region and the peripheral region each include at least one of the thin film transistors.

### CROSS-REFERENCE TO RELATED APPLICATIONS

The present disclosure is a National Phase Application filed under 35 U.S.C. 371 as a national stage of PCT/CN2024/093350 filed on May 15, 2024, and claims the priority to Chinese Patent Application No. 202310783705.4 filed on Jun. 29, 2023, the contents of which are incorporated herein by reference in their entirety.

### TECHNICAL FIELD

The present disclosure relates to the technical field of display, and particularly to a display substrate and a display panel.

### BACKGROUND

With development of display technology, the use of display panels has become more and more widespread. A Thin Film Transistor (TFT) Array (Array) substrate is a major component in a current display panel apparatus, and is configured to provide a driver circuit for a display substrate. In a traditional thin film transistor with a bottom gate structure, due to a relatively large overlapping area between a gate electrode and a source/drain electrode, a relatively large parasitic capacitance is generated, resulting in a delay of a signal, and since a length L of a channel of the manufactured thin film transistor is relatively large, the application of the thin film transistor is limited. In the related art, the hall mobility of a common metal oxide thin film transistor is about 10 cm²/V·s, but in order to meet the increasingly high expectations on resolution, a refresh rate and a narrow bezel of the display substrate, higher expectations are also put on the device characteristics of the thin film transistor.

### SUMMARY

Embodiments of the present disclosure provide a display substrate and a display panel.

In a first aspect, an embodiment of the present disclosure provides a display substrate, including a base substrate, a display region and a peripheral region surrounding the display region are arranged on the base substrate, the display substrate includes: a plurality of thin film transistors each including a gate electrode and an active pattern, the active pattern includes a first connection part, a second connection part, and a channel part connected between the first connection part and the second connection part, and the channel part and the gate electrode are opposite to each other and insulated from each other; the gate electrode of the thin film transistor is on a side of the active pattern away from the base substrate, and a Hall mobility of the active pattern of the thin film transistor is greater than or equal to 20 cm²/V·s; and the display region and the peripheral region each include at least one of the thin film transistors.

In some embodiments, a material of the active pattern includes any one or more of a metal oxide semiconductor or a silicon semiconductor, and a crystalline state of the active pattern includes any one or more of amorphous state, partially crystalline state, single crystalline state, or polycrystalline state.

In some embodiments, the thin film transistor further includes a light-shielding pattern on a side of the active pattern close to the base substrate, an orthographic projection of the light-shielding pattern on the base substrate overlaps an orthographic projection of the channel part on the base substrate.

In some embodiments, the orthographic projection of the light-shielding pattern on the base substrate covers and exceeds the orthographic projection of the channel part on the base substrate.

In some embodiments, the display substrate includes a first conducting layer on a side of the active pattern away from the base substrate; the thin film transistor further includes a first electrode and a second electrode both in the first conductive layer, the first electrode is connected to the first connection part, and the second electrode is connected to the second connection part; and an orthographic projection of the first electrode on the base substrate and an orthographic projection of the second electrode on the base substrate do not overlap the orthographic projection of the gate electrode on the base substrate.

In some embodiments, the plurality of thin film transistors include a plurality of first thin film transistors in the display region; the display substrate further includes a plurality of gate lines each extending in a first direction and a plurality of data lines each extending in a second direction, the data lines are in the first conductive layer; and the plurality of gate lines and the plurality of data lines define a plurality of pixel units, each of the pixel units includes one of the first thin film transistors and a corresponding pixel electrode, a part of the gate line also serves as a gate electrode of the first thin film transistor, a first electrode of the first thin film transistor is connected to the pixel electrode, and a second electrode of the first thin film transistor is connected to the data line.

In some embodiments, the gate electrode of the first thin film transistor and the light-shielding pattern are insulated from each other.

In some embodiments, an orthographic projection of the active pattern of the first thin film transistor on the base substrate is of an L-shaped pattern, the first connection part and the channel part each extend in the second direction, and the second connection part includes a part extending in the first direction and a part extending in the second direction.

In some embodiments, the plurality of thin film transistors includes a plurality of second thin film transistors in the peripheral region; and the first electrode, the second electrode and the gate electrode of the second thin film transistor are all conductive patterns extending along the second direction.

In some embodiments, an orthographic projection of the active pattern of the second thin film transistor on the base substrate is of a rectangular pattern, and the first connection part, the channel part, and the second connection part are sequentially arranged along the first direction.

In some embodiments, the plurality of second thin film transistors includes a plurality of first sub-transistors and a plurality of second sub-transistors, the light-shielding pattern and the gate electrode of the first sub-transistor are electrically connected; and the light-shielding pattern and the gate electrode of the second sub-transistor are insulated from each other.

In some embodiments, the first sub-transistor further includes a first transfer electrode in the first conductive layer, and the light-shielding pattern and the gate electrode of the first sub-transistor are electrically connected through the first transfer electrode.

In some embodiments, the display substrate further includes: a buffer layer between the light-shielding pattern and the active pattern; and an interlayer dielectric layer between the active pattern and the first conductive layer and on a side of the gate electrode away from the base substrate; the first transfer electrode is connected to the gate electrode through a first via and is connected to the light-shielding pattern through a second via, the first via is in the interlayer dielectric layer, and the second via penetrates through the interlayer dielectric layer and the buffer layer, and an orthographic projection of the first via on the base substrate and an orthographic projection of the second via on the base substrate do not overlap the orthographic projection of the active pattern on the base substrate.

In some embodiments, the first sub-transistor further includes a second transfer electrode in the same layer as the pixel electrode, and the light-shielding pattern and the gate electrode of the first sub-transistor are electrically connected through the second transfer electrode.

In some embodiments, the display substrate further includes: a buffer layer between the light-shielding pattern and the active pattern; an interlayer dielectric layer between the active pattern and the first conductive layer and on a side of the gate electrode away from the base substrate; and a passivation layer between the first conductive layer and the pixel electrode; the second transfer electrode is connected to the gate electrode through a third via and is connected to the light-shielding pattern through a fourth via, the third via penetrates through the interlayer dielectric layer and the passivation layer, and the fourth via penetrates through the interlayer dielectric layer, the passivation layer and the buffer layer, and an orthographic projection of the third via on the base substrate and an orthographic projection of the fourth via on the base substrate do not overlap the orthographic projection of the active pattern on the base substrate.

In some embodiments, the peripheral region includes a first peripheral sub-region, the first peripheral sub-region includes a first region on a side of the display region in the second direction, the display substrate further includes a plurality of multiplexing circuits in the first region, each of the multiplexing circuits is electrically connected to a selection control signal line, a driving signal line provided by a source driver chip and n data lines, and is configured to provide a data signal output by the source driver chip to the n data lines under control of the selection control signal line; and the multiplexing circuit includes at least one second sub-transistor, a part of the selection control signal line also serves as the gate electrode of the second sub-transistor, the first electrode of the second sub-transistor is connected to the driving signal line, and the second electrode of the second sub-transistor is connected to the data line corresponding to the multiplexing circuit to which the second sub-transistor belongs.

In some embodiments, multiple ones of the plurality of the multiplexing circuits constitute one multiplexing unit, and in a same multiplexing unit, first electrodes of different second sub-transistors corresponding to different multiplexing circuits are connected to a same driving signal line.

In some embodiments, the first peripheral sub-region further includes a second region on a side of the display region away from the first region, the display substrate further includes an electrostatic discharge protection circuit in the second region, the electrostatic discharge protection circuit is configured to discharge static electricity generated in the display substrate, and the electrostatic discharge protection circuit includes at least one second sub-transistor.

In some embodiments, the peripheral region further includes a second peripheral sub-region, the second peripheral sub-region includes a third region on a side of the second region away from the display region, and the display substrate further includes a touch detection circuit in the third region, the touch detection circuit includes at least one first sub-transistor.

In some embodiments, the second peripheral sub-region further includes fourth regions on both sides of the display region in the first direction, the display substrate further includes a gate driver circuit configured to provide a scan signal to the gate lines row by row, and the gate driver circuit includes multiple first sub-transistors.

In some embodiments, each of width-to-length ratios of channel parts of the first thin film transistor and the first sub-transistor is in a range from 5/5 to 60/5.

In some embodiments, a width-to-length ratio of the channel part of the second sub-transistor is in a range from 7.5/5 to 90/5.

In a second aspect, an embodiment of the present disclosure provides a display panel including the display substrate described above.

The display substrate provided by the embodiment of the present disclosure includes a plurality of thin film transistors, the active pattern act0 includes an oxide semiconductor material, and the gate electrode Gate is located on the side of the active pattern act0 away from the base substrate 10, that is, the thin film transistor is a top gate thin film transistor, the material of the active pattern act0 adopts a metal oxide semiconductor material with a relatively high mobility, and the Hall mobility is greater than or equal to 20 cm²/V·s. Therefore, based on the material and structural characteristics of the thin film transistor, the thin film transistor provided by the embodiment of the present disclosure can realize the improvement of the mobility, and can ensure the stability of the performance, the improvement of the mobility can realize a higher on-state current, and is beneficial to realizing the narrow bezel design of the display substrate. Moreover, the thin film transistors with the same structure are manufactured in the display region AA and the peripheral region NA, so that corresponding laminated structures in the thin film transistors can be formed in a same manufacturing process, which is beneficial to simplifying the manufacturing process and improving the manufacturing efficiency.

### BRIEF DESCRIPTION OF DRAWINGS

The accompanying drawings, which are included to provide a further understanding of the present disclosure and constitute a part of this specification, serve to explain the present disclosure together with the following specific embodiments, but do not constitute a limitation to the present disclosure.

FIG. 1 is a schematic plan view illustrating a structure of a display substrate according to an embodiment of the present disclosure.

FIG. 2 is a schematic plan view illustrating a structure of a thin film transistor in a display region according to an embodiment of the present disclosure.

FIG. 3 is a schematic cross-sectional view taken along a section line AA in FIG. 2.

FIG. 4 is a schematic plan view illustrating a structure of a thin film transistor in a peripheral region according to an embodiment of the present disclosure.

FIG. 5 is a schematic cross-sectional view illustrating a structure of a thin film transistor in a peripheral region according to an embodiment of the present disclosure.

FIG. 6a is a schematic plan view illustrating a structure of another thin film transistor in a peripheral region according to an embodiment of the present disclosure.

FIG. 6b is a schematic cross-sectional view taken along a section line CC in FIG. 6a.

FIG. 6c is a schematic cross-sectional view taken along a section line BB in FIG. 6a.

FIG. 7a is a schematic plan view illustrating a structure of another thin film transistor in a peripheral region according to an embodiment of the present disclosure.

FIG. 7b is a schematic cross-sectional view taken along a section line EE in FIG. 7a.

FIG. 7c is a schematic cross-sectional view taken along a section line DD in FIG. 7a.

FIG. 8 is a schematic plan view illustrating a structure of another thin film transistor in a peripheral region according to an embodiment of the present disclosure.

### REFERENCE CHARACTERS

display substrate: base substrate 10, second conductive layer 12, buffer layer BUF, active semiconductor layer Act, gate insulating layer GI, third conductive layer 13, interlayer dielectric layer ILD, first conductive layer 11, first passivation sub-layer PVX1, planarization layer PLN, fourth conductive layer 14, second passivation sub-layer PVX2, fifth conductive layer 15, data line DL, gate line GL, pixel electrode PIX, common electrode COM, first transfer electrode Z1, and second transfer electrode Z2;
base substrate: display area AA, peripheral area NA, first peripheral sub-region na1, second peripheral sub-region na2, first region q1, second region q2, third region q3, fourth region q4, bonding region BA, first direction X, and second direction Y;
thin film transistor: active pattern act0, light-shielding pattern S, first electrode/drain electrode t1, second electrode/source electrode t2, gate electrode Gate; first connection part 11, second connection part 12, and channel part g;
first via k1, second via k2, third via k3, fourth via k4, first sub-via k11, second sub-via k12, third sub-via 13, and fourth sub-via k14.

### DETAIL DESCRIPTION OF EMBODIMENTS

Embodiments of the present disclosure will be described in detail below in conjunction with the accompanying drawings. It should be understood that the specific embodiments described herein are only for illustration and explanation of the present disclosure, and are not intended to limit the present disclosure.

In order to make the objects, technical solutions and advantages of the embodiments of the present disclosure more clear, the technical solutions of the embodiments of the present disclosure will be clearly and completely described with reference to the accompanying drawings of the embodiments of the present disclosure. Obviously, the described embodiments are only some of the embodiments of the present disclosure, not all of the embodiments. All other embodiments, which may be obtained by one of ordinary skill in the art without any creative effort based on the embodiments in the present disclosure, fall within the protection scope of the present disclosure.

Unless defined otherwise, technical or scientific terms used in the embodiments of the present disclosure shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Similarly, the term “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may be changed accordingly.

It will be understood that when a layer or element is referred to as being “on” another layer or a substrate, the layer or element may be directly on the another layer or the substrate, or intervening layers may further exist therebetween.

Example embodiments are described herein with reference to cross-sectional and/or plan views as idealized example drawings. In the drawings, thicknesses of layers and regions are exaggerated for clarity. Variations from the illustrated shapes in the drawings as a result, for example, of manufacturing techniques and/or tolerances, can be imaged. Thus, the example embodiments should not be construed as limited to the shapes of regions illustrated herein but are to include deviations in shapes that result, for example, from manufacturing. For example, an etched region shown as a rectangle typically has a curved feature. Thus, the regions illustrated in the drawings are schematic in nature and their shapes are not intended to illustrate the actual shapes of the regions of a device and are not intended to limit the scope of exemplary embodiments.

It should be noted that, the term “in a same layer” in the embodiments of the present disclosure means that two structures are formed from a same material layer through a patterning process, and therefore both structures are in a same layer in terms of a stacking relationship, which does not mean distances between both structures and the base substrate 10 must be the same.

With development of display technology, the use of display panels has become more and more widespread. A Thin Film Transistor (TFT) Array (Array) substrate is a major component in a current display panel apparatus, and is configured to provide a driver circuit for a display substrate. In a traditional thin film transistor with a bottom gate structure, due to a relatively large overlapping area between a gate electrode and a source/drain electrode, a relatively large parasitic capacitance is generated, resulting in a delay of a signal, and since a length L of a channel of the manufactured thin film transistor is relatively large, the application of the thin film transistor is limited. In the related art, the Hall mobility of a common metal oxide thin film transistor is about 10 cm²/V·s, but in order to meet the increasingly high expectations on resolution, a refresh rate and a narrow bezel of the display substrate, higher expectations are also put on the device characteristics of the thin film transistor.

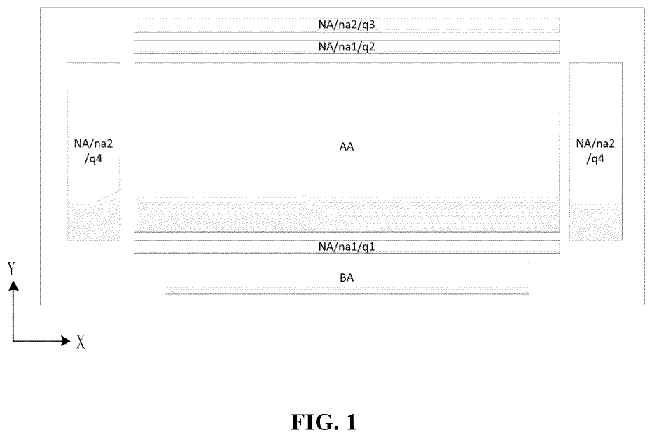

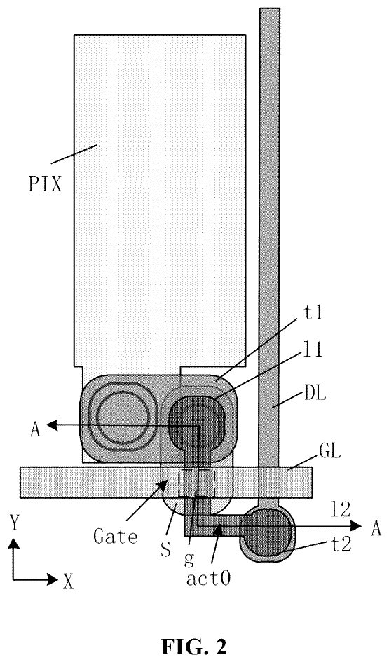

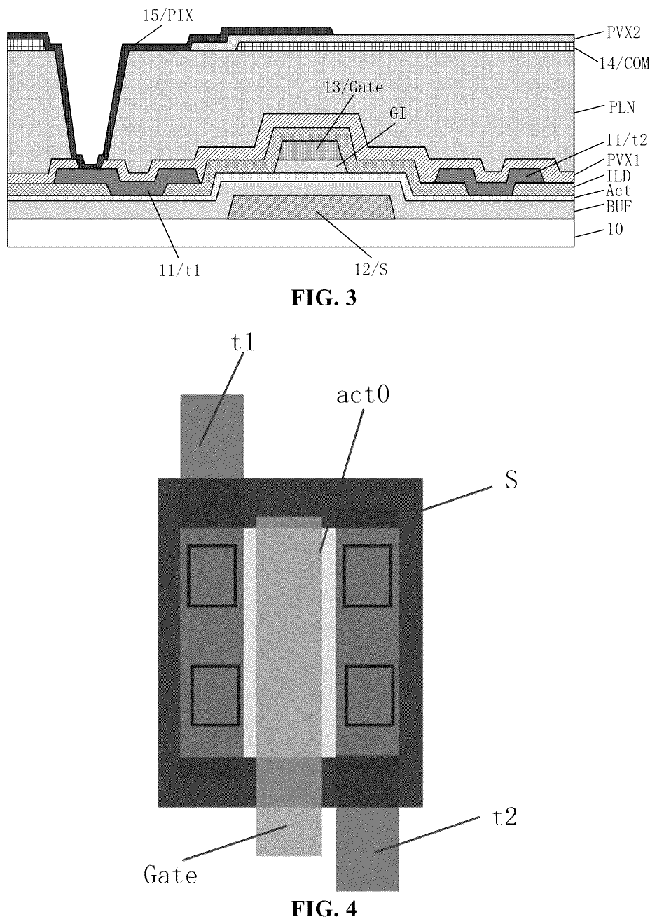

FIG. 1 is a schematic plan view illustrating a structure of a display substrate according to an embodiment of the present disclosure, FIG. 2 is a schematic plan view illustrating a structure of a thin film transistor in a display region according to an embodiment of the present disclosure, and FIG. 3 is a schematic cross-sectional view taken along a section line AA in FIG. 2.

In order to solve at least one or more of the above technical problems, an embodiment of the present disclosure provides a display substrate, including a base substrate 10, and a display region AA and a peripheral region NA surrounding the display region AA are arranged on the base substrate 10. The display substrate includes a plurality of thin film transistors each including a gate electrode Gate and an active pattern act0, the active pattern act0 includes a first connection part 11, a second connection part 12, and a channel part g connected between the first connection part 11 and the second connection part 12, and the channel part g and the gate electrode Gate are opposite to each other and insulated from each other. The gate electrode Gate of the thin film transistor is positioned on a side of the active pattern act0 away from the base substrate 10, and the Hall mobility of the active pattern act0 of the thin film transistor is greater than or equal to 20 cm²/V·s. The display region AA and the peripheral region NA each include at least one of the thin film transistors described above.

The display substrate provided by the embodiment of the present disclosure includes a plurality of thin film transistors, the active pattern act0 includes an oxide semiconductor material, and the gate electrode Gate is located on the side of the active pattern act0 away from the base substrate 10, that is, the thin film transistor is a top gate thin film transistor, the material of the active pattern act0 adopts a metal oxide semiconductor material with a relatively high mobility, and the Hall mobility is greater than or equal to 20 cm²/V·s. Therefore, based on the material and structural characteristics of the thin film transistor, the thin film transistor provided by the embodiment of the present disclosure can realize the improvement of the mobility, and can ensure the stability of the performance, the improvement of the mobility can realize a higher on-state current, and is beneficial to realizing the narrow bezel design of the display substrate. Moreover, the thin film transistors with the same structure are manufactured in the display region AA and the peripheral region NA, so that corresponding laminated structures in the thin film transistors can be formed in a same manufacturing process, which is beneficial to simplifying the manufacturing process and improving the manufacturing efficiency.

As shown in FIGS. 2 and 3, the display substrate includes a base substrate 10, and a second conductive layer 12, a buffer layer BUF, an active semiconductor layer Act, a gate insulating layer GI, a third conductive layer 13, an interlayer dielectric layer ILD, a first conductive layer 11, a first passivation sub-layer PVX1, a fourth conductive layer 14, a second passivation sub-layer PVX2, and a fifth conductive layer 15, which are sequentially disposed on a side of the base substrate 10. The first conductive layer 11 includes a data line DL, and a first electrode t1 and a second electrode t2 of the thin film transistor; the second conductive layer 12 includes a light-shielding pattern S of the thin film transistor; the third conductive layer 13 includes a gate line GL and a gate electrode Gate of the thin film transistor; the fourth conductive layer 14 includes a common electrode COM; and the fifth conductive layer 15 includes a pixel electrode PIX. In addition, a planarization layer PLN may be further disposed between the first passivation sub-layer PVX1 and the second passivation sub-layer PVX 2.

The buffer layer BUF may be a silicon oxide (SiOx) film, a silicon nitride (SiNx) film, or a composite film formed by alternately stacking a silicon oxide film and a silicon nitride film. The material of the gate insulating layer GI may include silicon oxynitride, silicon oxide, silicon nitride, silicon oxycarbide, silicon carbo-nitride, aluminum oxide, aluminum nitride, tantalum oxide, hafnium oxide, zirconium oxide, titanium oxide, or the like, and the gate insulating layer GI may be formed into a single layer or a plurality of layers. The material of the interlayer insulating layer may include, for example, a silicon compound, a metal oxide, or the like. The material of the passivation layer PVX may include, for example, silicon oxynitride, silicon oxide, silicon nitride, or the like. The planarization layer PLN may be made of an organic insulating material, which, for example, may include a resin material such as polyimide, epoxy, acryl, polyester, photoresist, polyacrylate, polyamide, or siloxane.

It should be noted that, one of the fourth conductive layer 14 and the fifth conductive layer 15 may include the common electrode COM, and the other of the fourth conductive layer 14 and the fifth conductive layer 15 may include the pixel electrode PIX, and a relationship between the fourth conductive layer 14 and the fifth conductive layer 15 that are stacked is not limited in the embodiment of the present disclosure. In the following embodiments, the structure shown in FIG. 3 is taken as a reference, that is, the pixel electrode PIX being located on a side of the common electrode COM away from the base substrate 10 is taken as an example for further description.

In addition, as shown in FIG. 1, a bonding region BA is further provided on the base substrate of the display substrate in the embodiment of the present disclosure, a plurality of bonding terminals are disposed in the bonding region BA, and the bonding terminals are configured to be connected to a driver chip and/or a flexible circuit board, to provide driving signals to the pixel units in the display region.

Specifically, a pattern structure of each layer is described in detail in connection with the following embodiments.

In some embodiments, the active pattern act0 is located in the active semiconductor layer Act, and a material of the active pattern act0 includes a metal oxide semiconductor material, and may specifically include any one or more of Indium Gallium Zinc Oxide (IGZO), Indium Gallium Oxide (IGO), Indium Gallium Zinc Tin Oxide (IGZTO), Indium Zinc Oxide (IZO), or rare earth element doped metal oxide (RE-OS), the rare earth element doped metal oxide may include lanthanide doped metal oxide (Ln-OS). The material of the active pattern act0 may alternatively include a silicon material, and specifically may include any one or more of amorphous silicon, monocrystalline silicon, or polycrystalline silicon. The crystalline state of the active pattern act0 may be one or more of amorphous state, partially crystalline state, single crystalline state, or polycrystalline state. In an example, the active pattern has a relatively high mobility and good optical stability, so that the Hall mobility of the corresponding thin film transistor can be raised to 20 cm²/(V·S) to 25 cm²/(V·S), and good characteristics can be maintained.

The thin film transistor further includes a light-shielding pattern S on a side of the active pattern act0 close to the base substrate 10, that is, the light-shielding pattern S is in the second conductive layer 12. There is an overlap between an orthographic projection of the light-shielding pattern S on the base substrate 10 and an orthographic projection of the channel part g on the base substrate.

It should be understood that the size of the light-shielding pattern S is related to the expectation on stability of the characteristics of the thin film transistor, and the larger the area of the light-shielding pattern S is, the more stable the characteristics of the thin film transistor is. In an example, the orthographic projection of the light-shielding pattern S on the base substrate 10 covers and exceeds the orthographic projection of the channel part g on the base substrate 10.

In an example, a material of the light-shielding pattern S may be a metal material, for example, the material of the light-shielding pattern S includes one or more of molybdenum (Mo), copper (Cu), or titanium (Ti), or an alloy thereof. In some embodiments of the present disclosure, the light-shielding pattern S is configured to shield the channel part g in the active pattern act0, so that heat generation in the thin film transistor is reduced, and light irradiation is prevented from affecting the stability of the active pattern act0.

In some embodiments, the first conductive layer 11 of the display substrate is located on a side of the active pattern act0 away from the base substrate 10. The thin film transistor further includes the first electrode t1 and the second electrode t2 in the first conductive layer 11, the first electrode t1 is connected to the first connection part 11, and the second electrode t2 is connected to the second connection part 12; and an orthographic projection of the first electrode t1 on the base substrate 10 and an orthographic projection of the second electrode t2 on the base substrate 10 do not overlap the orthographic projection of the gate electrode Gate on the base substrate 10.

The first electrode t1 and the second electrode t2 of the thin film transistor refer to a drain electrode and a source electrode of the thin film transistor, respectively, and correspondingly, the first connection part 11 in the active pattern act0 is a drain connection part, the second connection part 12 in the active pattern act0 is a source connection part, the source connection part is connected to the source electrode of the thin film transistor, and the drain connection part is connected to the drain electrode of the thin film transistor. Each of the source connection part and the drain connection part may be doped with an impurity (e.g., an N-type impurity or a P-type impurity) at a higher impurity concentration than that (i.e., the impurity concentration at which the channel part g is doped with the impurity) of the channel part g. The channel part g directly faces the gate electrode Gate of the thin film transistor, and in response to that a voltage signal applied to the gate electrode Gate reaches a certain value, a carrier path is formed in the channel part g to make the source electrode and the drain electrode of the thin film transistor conductive to each other, that is, a current is formed between the source electrode and the drain electrode of the thin film transistor.

Furthermore, the thin film transistor in the embodiment of the present disclosure is of a top gate structure, and since there is no overlap between the gate electrode Gate and each of the source electrode and the drain electrode, the thin film transistor has a lower parasitic capacitance, and the delay of the signal due to being transmitted can be reduced. Moreover, a self-aligned manufacturing method is adopted, so that a device with a shorter channel can be formed, thereby reducing a size of the device.

In some embodiments, the plurality of thin film transistors includes a plurality of first thin film transistors, and the first thin film transistors are located in the display region AA. The display substrate further includes a plurality of gate lines GL extending along a first direction X and a plurality of data lines DL extending along a second direction Y, the gate lines GL are located in the third conductive layer 13, and the data lines DL are located in the first conductive layer 11. The plurality of gate lines GL and the plurality of data lines DL define a plurality of pixel units, each of the pixel units includes a first thin film transistor and a pixel electrode PIX corresponding thereto, the pixel electrode PIX is located in the fifth conductive layer 15.

A part of the gate line GL of the display substrate also serves as the gate electrode Gate of the first thin film transistor, the first electrode t1 of the first thin film transistor is connected to the pixel electrode PIX, and the second electrode t2 of the first thin film transistor is connected to the data line DL. The pixel electrode PIX is located in the fifth conductive layer 15.

In some embodiments, the gate electrode Gate and the light-shielding pattern S of the first thin film transistor are disposed to be insulated from each other, i.e., the light-shielding pattern S of the first thin film transistor is a metal pattern independently existing without being connected to any other structure, which does not increase the parasitic capacitance of the first thin film transistor additionally. The light-shielding pattern S in the first thin film transistor only has a light-shielding effect, and prevents the influence of light on the channel region in the active pattern act0, so as to increase the stability of the on-state current.

The first thin film transistor in the display region AA according to the embodiment of the present disclosure has a parasitic capacitance Cgs=3.85 fF, which is measured in a case where the width-to-length ratio of the channel part g of the active pattern act0 is 5 μm/4 μm. Compared with a conventional bottom gate thin film transistor, in the related art, with the parasitic capacitance Cgs=7.39 fF, the parasitic capacitance Cgs of the first thin film transistor in the embodiment of the present disclosure is reduced by ½, which is beneficial to reducing a feed-through voltage of the pixel unit and reducing a load capacitance on the scanning line.

In some embodiments, as shown in FIG. 3, an orthographic projection of the active pattern act0 of the first thin film transistor on the base substrate 10 is of an L-shaped pattern, the first connection part 11 and the channel part g each extend in the second direction Y, and the second connection part 12 includes a part extending in the first direction X and a part extending in the second direction Y.

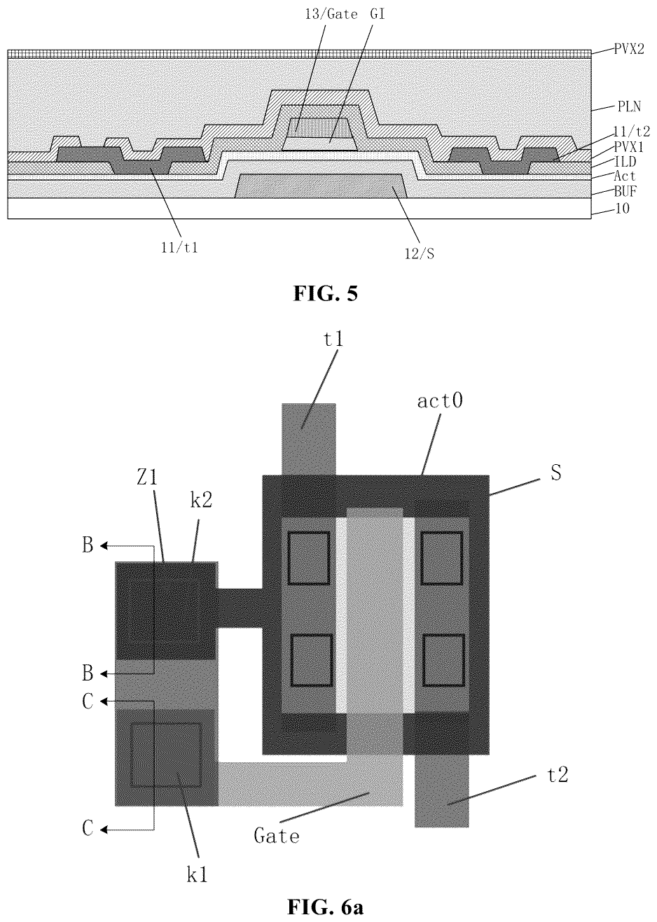

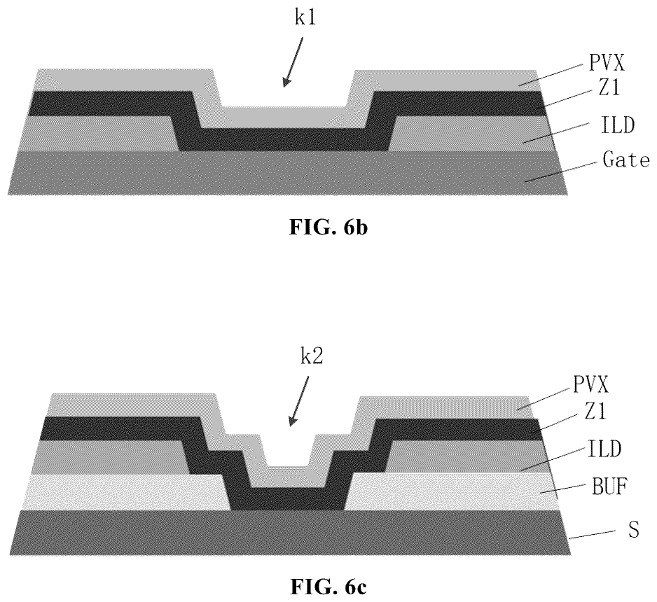

FIG. 4 is a schematic plan view illustrating a structure of a thin film transistor in a peripheral region according to an embodiment of the present disclosure, and FIG. 5 is a schematic cross-sectional view illustrating a structure of a thin film transistor in a peripheral region according to an embodiment of the present disclosure.

In some embodiments, as shown in FIGS. 4 and 5, the plurality of thin film transistors includes a plurality of second thin film transistors, and the second thin film transistors are located in the peripheral region NA; a first electrode t1, a second electrode t2, and a gate electrode Gate of the second thin film transistor are conductive patterns extending in the second direction Y.

In the embodiment of the present disclosure, the thin film transistors with the same structure are manufactured in the display region AA and the peripheral region NA, so that corresponding laminated structures in the thin film transistors can be formed in a same manufacturing process, which is beneficial to simplifying the manufacturing process and improving the manufacturing efficiency.

In addition, as shown in FIG. 5, a plurality of vias may be disposed between the first electrode of the thin film transistor and the first connection part of the active pattern, and between the second electrode of the thin film transistor and the second connection part of the active pattern, so as to reduce the parasitic capacitance in the thin film transistor.

In some embodiments, as shown in FIG. 4, an orthographic projection of the active pattern act0 of the second thin film transistor on the base substrate 10 is of a rectangular pattern, and the first connection part 11, the channel part g and the second connection part 12 are arranged in sequence along the first direction X. Referring to FIGS. 2 and 4, although the thin film transistors in the display region AA and the peripheral region NA have the same stacked structure, but active patterns act0 of the thin film transistors in different regions have different shapes in plan views thereof.

In some embodiments, the plurality of second thin film transistors includes a plurality of first sub-transistors and a plurality of second sub-transistors, the light-shielding pattern S and the gate electrode Gate of the first sub-transistor are electrically connected; and the light-shielding pattern S and the gate electrode Gate of the second sub-transistor are insulated from each other.

In an embodiment of the present disclosure, the light-shielding pattern S and the gate electrode Gate of the first sub-transistor is electrically connected, so as to form a dual-gate structure, that is, the light-shielding pattern S also serves as a bottom gate, and the light-shielding pattern S is electrically connected to the gate electrode Gate, so that two conductive channels are formed, resulting in an increased on-state current, the negative drift of a threshold voltage is effectively inhibited, and the mobility of carriers is improved, thereby facilitating the narrow bezel design.

Table 1 shows comparative data obtained by manufacturing and detecting the first sub-transistor and the second sub-transistor provided in the embodiment of the present disclosure. As shown in table 1, in a case where channel parts g of active patterns act0 corresponding to the first sub-transistor LS-0 and the second sub-transistor LS-F have the same width-to-length ratio, three different threshold voltages Vds are respectively provided for the first sub-transistors LS-0 and the second sub-transistors LS-F, and it can be seen that the on-state currents of the first sub-transistors LS-0 and the second sub-transistors LS-F are close or approximate to each other, but the Vth of the second sub-transistor LS-F is significantly negatively shifted as the threshold voltage Vds increases. By contrast, two conductive channels are formed in the first sub-transistor LS-0, so that the on-state current is increased, the negative drift of the threshold voltage is effectively inhibited, and the mobility of carriers is improved, thereby facilitating the narrow bezel design.

TABLE 1

| | LS-0 | | | LS-F | | |
|---|---|---|---|---|---|---|
| | Vds = | Vds = | Vds = | Vds = | Vds = | Vds = |
| | 0.1 V | 7.6 V | 15.1 V | 0.1 V | 7.6 V | 15.1 V |
| W[um] | 10 | 10 | 10 | 10 | 10 | 10 |
| L[um] | 6 | 6 | 6 | 6 | 6 | 6 |
| Vth@10 nA | 1.80 | 1.33 | 1.14 | 0.94 | −0.41 | −1.85 |
| SS | 0.29 | 0.25 | 0.22 | 0.41 | 0.32 | 0.30 |
| Ion@15 V | 4.16E−07 | 2.27E−05 | 3.20E−05 | 4.47E−07 | 2.35E−05 | 3.38E−05 |
| Ion@10 V | 2.46E−07 | 1.06E−05 | 1.29E−05 | 2.74E−07 | 1.15E−05 | 1.60E−05 |

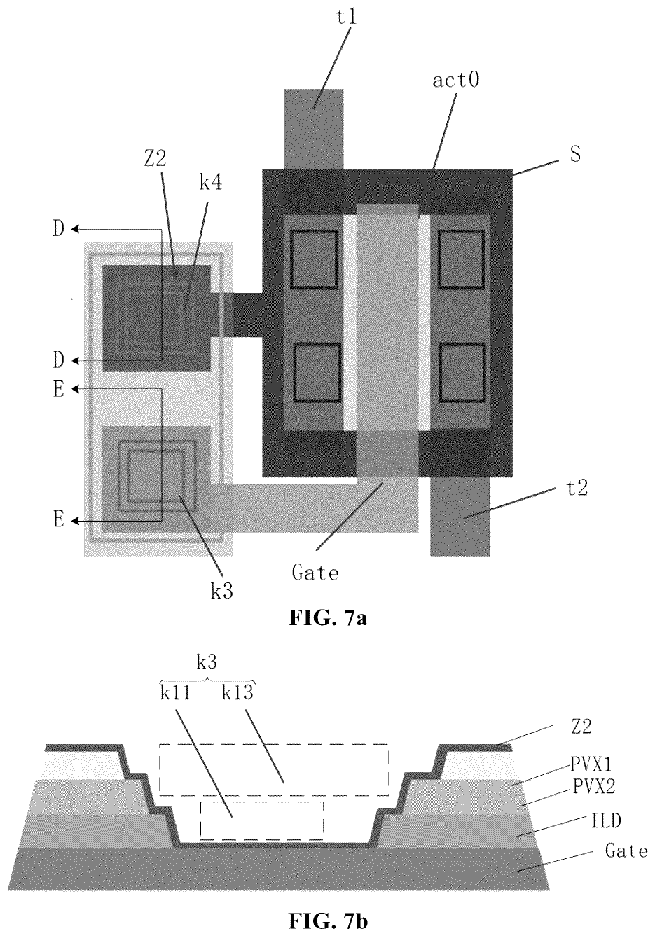

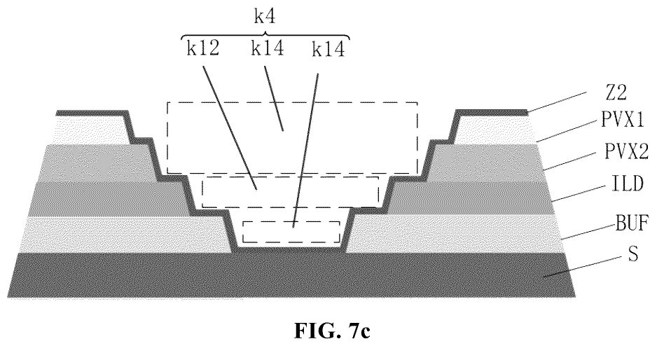

FIG. 6a is a schematic plan view illustrating a structure of another thin film transistor in a peripheral region according to an embodiment of the present disclosure, FIG. 6b is a schematic cross-sectional view taken along a section line CC in FIG. 6a, and FIG. 6c is a schematic cross-sectional view taken along a section line BB in FIG. 6a. FIG. 7a is a schematic plan view illustrating a structure of another thin film transistor in a peripheral region according to an embodiment of the present disclosure, FIG. 7b is a schematic cross-sectional view taken along a section line EE in FIG. 7a, and FIG. 7c is a schematic cross-sectional view taken along a section line DD in FIG. 7a.

In some embodiments, to achieve the electrical connection between the light-shielding pattern S and the gate electrode Gate in the first sub-transistor, the light-shielding pattern S and the gate electrode Gate extend to a position that does not overlap the active pattern act0 in a thickness direction (i.e., a direction in which the thickness of the display substrate extends) of the display substrate, and are connected through a via.

In some embodiments, as shown in FIG. 6a, the first sub-transistor further includes a first transfer electrode Z1, the first transfer electrode Z1 is located in the first conductive layer 11, the light-shielding pattern S and the gate electrode Gate of the first sub-transistor are electrically connected through the first transfer electrode Z1. That is, the first transfer electrode Z1 is disposed in the same layer as the source/drain electrode of the first sub-transistor.

In some embodiments, as shown in FIGS. 6b and 6c, the first transfer electrode Z1 is connected to the gate electrode Gate through a first via k1, and connected to the light-shielding pattern S through a second via k2, the first via k1 is located in the interlayer dielectric layer ILD, and the second via k2 penetrates through the interlayer dielectric layer ILD and the buffer layer BUF. An orthographic projection of the first via k1 on the base substrate 10 and an orthographic projection of the second via k2 on the base substrate 10 do not overlap the orthographic projection of the active pattern act0 on the base substrate 10.

It should be understood that, during forming the second via k2, no separate mask is used for etching the buffer material film, but the same mask as that for the interlayer dielectric material film is used, thereby saving one mask to save the manufacturing cost.

That is, the first via k1 is firstly formed in the interlayer dielectric material film, and then a second etching is performed to form the second via k2 penetrating through the buffer material film and the interlayer dielectric material film. Since the same mask is used for the buffer material film and the interlayer dielectric material film, the second etching for the interlayer dielectric material film is equivalent to an over-etching. However, an active material film is on the side of the interlayer dielectric layer ILD close to the base substrate 10, and therefore, the risk of damaging the active pattern act0 exists during performing the over-etching on the interlayer dielectric layer ILD.

As shown in FIG. 5, the first conductive layer 11 is located on a side of the interlayer dielectric layer ILD away from the active semiconductor layer Act, the active semiconductor layer Act is located between the interlayer dielectric ILD and the buffer layer BUF, and the first transfer electrode Z1 is located in the first conductive layer 11. In this case, since both the buffer layer BUF and the interlayer dielectric layer ILD are to be etched for forming the second via k2, the active pattern Act0 in the active semiconductor layer Act may be damaged.

In order to solve the above technical problem, as shown in FIG. 7a, in the display substrate provided in the embodiment of the present disclosure, the light-shielding pattern S and the gate electrode Gate in the first sub-transistor are connected through the second transfer electrode Z2, and the second transfer electrode Z2 is disposed in the same layer as the pixel electrode PIX.

In some embodiments, as shown in FIGS. 7b and 7c, the second transfer electrode Z2 is connected to the gate electrode Gate through a third via k3, and is connected to the light-shielding pattern S through a fourth via k4, the third via k3 penetrates through the interlayer dielectric layer ILD and the passivation layer, and the fourth via k4 penetrates through the interlayer dielectric layer ILD, the passivation layer and the buffer layer BUF. An orthographic projection of the third via k3 on the base substrate 10 and an orthographic projection of the fourth via k4 on the base substrate 10 do not overlap the orthographic projection of the active pattern act0 on the base substrate 10.

Referring to FIG. 5, the passivation layer includes a first passivation sub-layer PVX1 and a second passivation sub-layer PVX2, the first passivation sub-layer PVX1 is located on a side of the first conductive layer 11 away from the base substrate 10, and the second passivation sub-layer PVX2 is located on a side of the first passivation sub-layer PVX1 away from the base substrate 10. In addition, referring to FIG. 3, in the display region AA of the display substrate, the first passivation sub-layer PVX1 is located between the pixel electrode PIX in the fifth conductive layer 15 and the drain electrode in the first conductive layer 11, and the second passivation sub-layer PVX2 is located between the pixel electrode PIX in the fifth conductive layer 15 and the common electrode COM in the fourth conductive layer 14.

It should be noted that the display substrate may further include a planarization layer PLN located between the first passivation sub-layer PVX1 and the second passivation sub-layer PVX2, and in this case, the third via k3 and the fourth via k4 each penetrate through the planarization layer PLN.

It should be noted that, the process of forming the third via k3 includes two steps. That is, a first sub-via k11 is firstly formed in the interlayer dielectric material film, and then a third sub-via k13 located above the first sub-via k11 is formed in the first passivation material film and the second passivation material film. That is, the first sub-via k11 and the third sub-via k13 together form the third via k3.

Similarly, the process of forming the fourth via k4 also includes two steps. That is, a second sub-via k12 is firstly formed in the interlayer dielectric material film, and then a fourth sub-via k14 communicating with the second sub-via k12 is formed in the first passivation material film, the second passivation material film and the buffer material film. That is, the second sub-via k12 and the fourth sub-via k14 jointly form the fourth via k4.

Therefore, during forming a via in the buffer material film, the via is formed in the same mask process as that for forming a via in the first passivation material film and the second passivation material film, without using a separate mask. In this case, the via formed in the buffer material film is formed through the second sub-via k12, that is, the interlayer dielectric layer ILD is not affected during forming the via in the buffer material film, and the over-etching on the interlayer dielectric material film is avoided, so that the active pattern act0 is prevented from being damaged.

In the first sub-transistor located in the peripheral region NA provided by the embodiment of the present disclosure, the light-shielding pattern S also serves as the bottom gate to form the thin film transistor with the double-gate structure, so that the source electrode and the drain electrode of the first sub-transistor are subjected to the action of the positive gate voltage of the bottom gate to generate carriers in an accumulated manner, the resistances of the source electrode and the drain electrode are greatly reduced, the heat generation in the first sub-transistor is reduced, and the damage on the first sub-transistor is reduced.

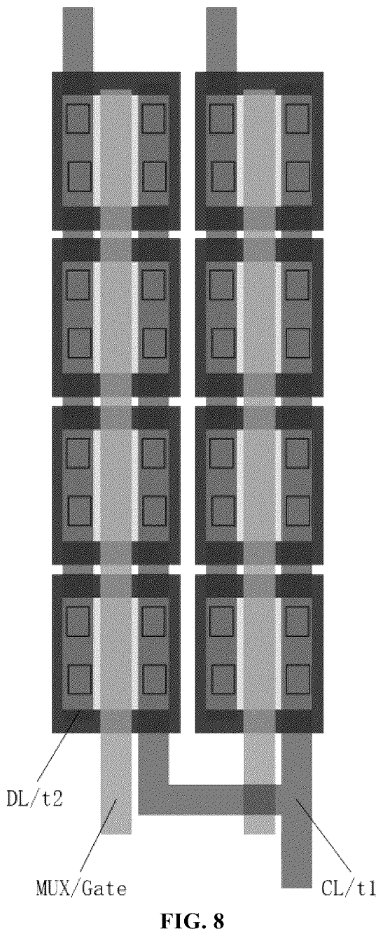

FIG. 8 is a schematic plan view illustrating a structure of another thin film transistor in a peripheral region according to an embodiment of the present disclosure.

In some embodiments, the peripheral region NA includes a first peripheral sub-region na1, and the first peripheral sub-region na1 includes a first region located on a side of the display region AA in the second direction Y. The display substrate further includes a plurality of multiplexing circuits in the first region, the multiplexing circuits each are electrically connected to a selection control signal line, a driving signal line provided by a source driver chip, and n data lines DL, and configured to provide the data signal output by the source driver chip to the n data lines DL under the control of the selection control signal line.

As shown in FIG. 8, the multiplexing circuit includes at least one second sub-transistor, a part of the selection control signal line MUX also serves as a gate electrode Gate of the second sub-transistor, a first electrode t1 of the second sub-transistor is connected to the driving signal line, and a second electrode t2 of the second sub-transistor is connected to the data line DL corresponding to the multiplexing circuit to which the second sub-transistor belongs.

In some embodiments, as shown in FIG. 8, multiple multiplexing circuits form a multiplexing unit, and in the same multiplexing unit, first electrodes t1 of different second sub-transistors corresponding to different multiplexing circuits are connected to a same driving signal line CL.

Specifically, any multiplexing unit may include multiple multiplexing circuits, any of the multiplexing circuits may correspondingly have at least one second sub-transistor. In response to that any multiplexing circuit correspondingly has multiple second sub-transistors, light-shielding patterns S of the second sub-transistors are respectively arranged independently, which is favorable for keeping a good heat dissipation state of the multiplexing circuit, and the stability of the device is further ensured. Further, the first electrodes t1 of the second sub-transistors corresponding to the multiple multiplexing circuits in any multiplexing unit may be connected to a same driving signal line CL.

In some embodiments, as shown in FIG. 1, the first peripheral sub-region na1 further includes a second region located on a side of the display region AA away from the first region, and the display substrate further includes an electrostatic discharge protection circuit positioned in the second region, and the electrostatic discharge protection circuit is configured to release static electricity generated in the display substrate, and the electrostatic discharge protection circuit includes at least one second sub-transistor.

The second sub-transistor in the electrostatic discharge protection circuit in the second region has the same structure as the transistor in FIG. 5, and is not repeated herein.

In some embodiments, as shown in FIG. 1, the peripheral region NA further includes a second peripheral sub-region na2, the second peripheral sub-region na2 includes a third region, and the third region is located on a side of the second region away from the display region AA. The display substrate further includes a touch detection circuit, which is positioned in the third region and includes at least one first sub-transistor.

In some embodiments, as shown in FIG. 1, the second peripheral sub-region na2 further includes fourth regions located on two sides of the display region AA along the first direction X, and the display substrate further includes a gate driver circuit configured to provide a scan signal to the gate lines GL row by row, and the gate driver circuit includes multiple first sub-transistors.

In the embodiment of the present disclosure, the first sub-transistor with the active pattern act0 formed by the metal oxide semiconductor material with a relatively high mobility is applied to the gate driver circuit. Compared with the conventional oxide thin film transistor, the on-state current Ion is increased by about 8 times or about 5 times, and without changing the original circuit structure of the gate driver circuit, the driving capability of the gate driver circuit can be greatly improved, the size of the thin film transistor in the gate driver circuit can be reduced, the single-side driving design with a relatively high resolution can be realized, the left and right bezels of the panel can be saved, and the panel can have a display appearance with ultra-narrow bezels.

In the first sub-transistors in the touch detection circuit in the third region and the gate driving circuit in the fourth region, the light-shielding pattern S and the corresponding gate electrode Gate may be connected through the first transfer electrode Z1 shown in FIG. 6a, or the light-shielding pattern S and the corresponding gate electrode Gate may be connected through the second transfer electrode Z2 shown in FIG. 7a, which is not limited in the embodiment of the present disclosure.

Table 2 shows a plurality of sets of width-to-length ratios of the first sub-transistor and the second sub-transistor (the first thin film transistor) provided in the embodiments of the present disclosure, a first comparative example, and a second comparative example in a load circuit under different conditions. Both the first comparative example and the second comparative example form a bottom gate thin film transistor by a Back Channel Etch (BCE) process, but the material of the active pattern act0 in the first comparative example is the same as that in the embodiment of the present disclosure, and the material of the active pattern act0 in the second comparative example is a conventional oxide material. As can be seen from table 2, in the same load circuit, that is, under the condition of realizing the same on-state current, the width-to-length ratio and an overall size of the first sub-transistor and the second sub-transistor provided in the embodiments of the present disclosure both are significantly less than those of the thin film transistor in the comparative examples, thereby facilitating the realization of a narrow bezel design.

TABLE 2

| Unit: μm | | loading1 | loading2 | loading3 | loading4 | loading5 |
|---|---|---|---|---|---|---|
| first | L | 5 | 5 | 5 | 5 | 5 |
| sub- | W | 5 | 10 | 15 | 20 | 25 |
| transistor | Total width of device | 29 | 29 | 29 | 29 | 29 |
| | Total width of device | 15 | 20 | 25 | 30 | 35 |
| second | L | 5 | 5 | 5 | 5 | 5 |
| sub- | W | 7.5 | 15 | 22.5 | 30 | 37.5 |
| transistor | Total width of device | 29 | 29 | 29 | 29 | 29 |
| | Total width of device | 17.5 | 25 | 32.5 | 40 | 47.5 |
| First | L | 5 | 5 | 5 | 5 | 5 |
| comparative | W | 40 | 80 | 120 | 160 | 200 |
| example | Total width of device | 29 | 29 | 29 | 29 | 29 |
| | Total width of device | 50 | 90 | 130 | 170 | 210 |
| Second | L | 5 | 5 | 5 | 5 | 5 |
| comparative | W | 21.25 | 42.5 | 63.75 | 85 | 106.25 |
| example | Total width of device | 29 | 29 | 29 | 29 | 29 |
| | Total width of device | 31.25 | 52.5 | 73.75 | 95 | 116.25 |

| loading6 | loading7 | loading8 | loading9 | loading10 | loading11 | loading12 |
|---|---|---|---|---|---|---|
| 5 | 5 | 5 | 5 | 5 | 5 | 5 |
| 30 | 35 | 40 | 45 | 50 | 55 | 60 |
| 29 | 29 | 29 | 29 | 29 | 29 | 29 |
| 40 | 45 | 50 | 55 | 60 | 65 | 70 |
| 5 | 5 | 5 | 5 | 5 | 5 | 5 |
| 45 | 52.5 | 60 | 67.5 | 75 | 82.5 | 90 |
| 29 | 29 | 29 | 29 | 29 | 29 | 29 |
| 55 | 62.5 | 70 | 77.5 | 85 | 92.5 | 100 |
| 5 | 5 | 5 | 5 | 5 | 5 | 5 |
| 240 | 280 | 320 | 360 | 400 | 440 | 480 |
| 29 | 29 | 29 | 29 | 29 | 29 | 29 |
| 250 | 290 | 330 | 370 | 410 | 450 | 490 |
| 5 | 5 | 5 | 5 | 5 | 5 | 5 |
| 127.5 | 148.75 | 170 | 191.25 | 212.5 | 233.75 | 255 |
| 29 | 29 | 29 | 29 | 29 | 29 | 29 |
| 137.5 | 158.75 | 180 | 201.25 | 222.5 | 243.75 | 265 |

Based on the same inventive concept, an embodiment of the present disclosure further provides a method for manufacturing a display substrate, for manufacturing the display substrate in any of the embodiments described above.

In the following, the manufacturing and formation of the above-described first thin film transistor (second sub-transistor), the first sub-transistor including the first transfer electrode Z1, and the first sub-transistor including the second transfer electrode Z2, in the present application, are described in detail by referring to specific examples.

### EXAMPLE 1

The first thin film transistor shown in FIG. 2 and FIG. 3 is formed through following steps S11 to S20.

In step S11, a base substrate 10 is provided, a light-shielding pattern S is formed on the base substrate 10, a buffer layer BUF is formed on a side of the light-shielding pattern S away from the base substrate 10, and a metal oxide semiconductor film is formed on a side of the buffer layer BUF away from the base substrate 10.

The base substrate 10 is a glass substrate, but is not limited thereto, and alternatively may be a PI substrate or other substrates. The buffer layer BUF can prevent ions in the glass substrate or a quartz substrate from moving into the thin film transistor to affect the performance of the thin film transistor. Specifically, the material of the buffer layer BUF may be an oxide, a nitride, or an oxynitride compound.

In step S12, the oxide semiconductor film is patterned to form an active pattern act0. A gate insulating layer GI covering the active pattern act0 is formed on the buffer layer BUF, and a third metal film is deposited on the gate insulating layer GI.

In step S13, a photoresist layer is formed on the gate insulating layer GI, and a photoresist pattern is formed by a patterning process to define a position of a gate electrode Gate.

In step S14, taking the photoresist pattern as a first mask, the third metal film is etched to form the gate electrode Gate.

In step S15, taking the photoresist pattern and the gate electrode Gate as a second mask, the gate insulating layer GI is etched to form a corresponding gate insulating pattern.

In step S16, taking the photoresist pattern, the gate electrode Gate and the gate insulating pattern as a third mask, the active pattern act0 is made to be conductive, and the photoresist material is stripped off after the active pattern act0 is conductive.

In the active pattern act0 being conductive, the first connection part 11 and the second connection part 12 become conductors, and the channel part g maintains characteristics of a semiconductor.

In step S17, an interlayer dielectric film is formed on the active pattern act0 and the gate electrode Gate, and a source contact hole and a drain contact hole are formed in the interlayer dielectric film.

In step S18, a first metal film is formed on the interlayer dielectric layer ILD, and a first electrode t1 and a second electrode t2 of the first thin film transistor are formed through patterning, the first electrode t1 is connected to the first connection part 11 through the drain contact hole, and the second electrode t2 is connected to the second connection part 12 through the source contact hole.

In step S19, a first passivation sub-layer PVX1 covering the first electrode t1 and the second electrode t2 of the first thin film transistor is formed on the interlayer dielectric layer ILD.

Alternatively, after step S19, the method further includes: forming a planarization layer on the first passivation sub-layer PVX1, forming a common electrode COM on the planarization layer, and then forming a second passivation sub-layer PVX2 on the planarization layer PLN to cover the common electrode COM; forming a via penetrating through the second passivation sub-layer PVX2, the planarization layer PLN, and the first planarization layer PLN; forming a pixel electrode PIX on the second passivation sub-layer PVX2, the pixel electrode PIX is connected to the first electrode t1 of the first thin film transistor through the via described above. Thus, the manufacturing of the display substrate including the first thin film transistor is completed.

### EXAMPLE 2

The first sub-transistor including the first transfer electrode Z1 is formed through following steps S21 to S29, steps S21 to S26 and S29 are the same as steps S11 to S16 and S19 in the example 1, and are not described again, and only the processes of forming the first via k1 and the second via k2 are shown in detail, and are specifically described below.

In step S27, an interlayer dielectric material film is formed over the active pattern act0 and the gate electrode Gate, and a first via k1, a source contact hole and a drain contact hole are formed by patterning the interlayer dielectric material film through a first transfer mask. Further, patterning is performed again through the first transfer mask to form the second via k2 penetrating through the interlayer dielectric material film and the buffer material film, and a final interlayer dielectric layer ILD and a final buffer layer BUF are formed.

It should be noted that the first via k1 formed in the interlayer dielectric film is configured to connect the first transfer electrode Z1 with the gate electrode Gate, and the second via k2 is configured to connect the first transfer electrode Z1 with the light-shielding pattern S. Furthermore, in the process of forming the second via k2, no separate mask is used for etching the buffer material film, but the same mask as that for the interlayer dielectric material film is used, so that one mask is saved, and the manufacturing cost is saved.

In step S28, a first metal thin film is formed on the interlayer dielectric layer ILD, and a first transfer electrode Z1, and a first electrode t1 and a second electrode t2 of the first thin film transistor are formed through a patterning process.

The first electrode t1 is connected to the first connection part 11 through the drain contact hole, and the second electrode t2 is connected to the second connection part 12 through the source contact hole; the first transfer electrode Z1 is connected to the gate electrode Gate through the first via k1 and connected to the light-shielding pattern S through the second via k2, so that the gate electrode Gate and the light-shielding pattern S are connected, to form the dual-gate structure of the first sub-transistor.

### EXAMPLE 3

The first sub-transistor including the second transfer electrode Z2 is formed through following steps S31 to S39, steps S31 to S26 and S38 are the same as steps S11 to S16 and S18 in the example 1, and are not described again, and only the processes of forming the third via k3 and the fourth via k4 are shown in detail, and are specifically described below.

In step S37, an interlayer dielectric material film is formed on the active pattern act0 and the gate electrode Gate, and a first sub-via k11, a second sub-via k12, a source contact hole and a drain contact hole are formed by patterning the interlayer dielectric material film through a second transfer mask.

In step S39, a first passivation film and a second passivation film covering the first electrode t1 and the second electrode t2 of the first thin film transistor is formed on the interlayer dielectric layer ILD, and through the second transfer mask, a third sub-via k13 penetrating through the first passivation film and the second passivation film is formed, and a fourth sub-via k14 penetrating through the first passivation film, the second passivation film and the buffer material film is formed. The above-described third sub-via k13 is connected to the first sub-via k11, and the fourth sub-via k14 is connected to the second sub-via k12.

In an example, an orthographic projection of the first sub-via k11 on the base substrate 10 partially overlaps an orthographic projection of the third sub-via k13 on the base substrate 10; an orthographic projection of the second sub-via k12 on the base substrate 10 partially overlaps an orthographic projection of the fourth sub-via k14 on the base substrate 10. Alternatively, as shown in FIGS. 7b and 7c, the orthographic projection of the third sub-via k13 on the base substrate 10 covers the orthographic projection of the first sub-via k11 on the base substrate 10; the orthographic projection of the fourth sub-via k14 formed in the first passivation material film and the second passivation material film on the base substrate 10 covers the orthographic projection of the second sub-via k12 on the base substrate 10.

It should be noted that, the process of forming the third via k3 includes two steps. That is, a first sub-via k11 is firstly formed in the interlayer dielectric material film, and then a third sub-via k13 located above the first sub-via k11 is formed in the first passivation material film and the second passivation material film. That is, the first sub-via k11 and the third sub-via k13 together form the third via k3.

Similarly, the process of forming the fourth via k4 also includes two steps. That is, a second sub-via k12 is firstly formed in the interlayer dielectric material film, and then a fourth sub-via k14 communicating with the second sub-via k12 is formed in the first passivation material film, the second passivation material film and the buffer material film. That is, the second sub-via k12 and the fourth sub-via k14 jointly form the fourth via k4. Therefore, during forming a via in the buffer material film, the via is formed in a same mask process as that for etching the first passivation material film and the second passivation material film, without using a separate mask, thereby saving one mask, so that the manufacturing cost is saved.

In step S30, a fifth metal material film is formed on the second passivation material film, a second transfer electrode Z2 is formed through patterning, the second transfer electrode Z2 is connected to the gate electrode Gate through the third via k3, and is connected to the light-shielding pattern S through the fourth via k4, so that the gate electrode Gate and the light-shielding pattern S are connected, to form the dual-gate structure of the first sub-transistor.

An embodiment of the present disclosure further provides a display panel, which includes the display substrate described above.

The above display panel may be any product or component with a display function, such as an electronic paper, a mobile phone, a tablet computer, a television, a monitor, a notebook computer, a digital photo frame, a navigator or the like, which is not limited by the present disclosure.

It will be understood that the above embodiments are merely exemplary embodiments adopted to illustrate the principles of the present disclosure, and the present disclosure is not limited thereto. It will be apparent to one of ordinary skill in the art that various changes and modifications can be made without departing from the scope of the present disclosure, and these changes and modifications also fall within the protection scope of the present disclosure.

1. A display substrate, comprising a base substrate, wherein a display region and a peripheral region surrounding the display region are arranged on the base substrate, the display substrate comprises:
a plurality of thin film transistors each comprising a gate electrode and an active pattern, wherein the active pattern comprises a first connection part, a second connection part, and a channel part connected between the first connection part and the second connection part, and the channel part and the gate electrode are opposite to each other and insulated from each other;
the gate electrode of each of the thin film transistors is on a side of the active pattern away from the base substrate, and a Hall mobility of the active pattern of each of the thin film transistors is greater than or equal to 20 cm²/V·s; and
the display region and the peripheral region each comprise at least one of the thin film transistors.

2. The display substrate according to claim 1, wherein a material of the active pattern is any one or more of a metal oxide semiconductor or a silicon semiconductor, and a crystalline state of the active pattern is any one or more of amorphous state, partially crystalline state, single crystalline state, or polycrystalline state.

3. The display substrate according to claim 1, wherein
the thin film transistor further comprises a light-shielding pattern on a side of the active pattern close to the base substrate, wherein an orthographic projection of the light-shielding pattern on the base substrate overlaps an orthographic projection of the channel part on the base substrate.

4. The display substrate according to claim 3, wherein the orthographic projection of the light-shielding pattern on the base substrate covers and exceeds the orthographic projection of the channel part on the base substrate.

5. The display substrate according to claim 3, wherein the display substrate comprises a first conducting layer on a side of the active pattern away from the base substrate;
each of the thin film transistors further comprises a first electrode and a second electrode in the first conductive layer, wherein the first electrode is connected to the first connection part, and the second electrode is connected to the second connection part; and
an orthographic projection of the first electrode on the base substrate and an orthographic projection of the second electrode on the base substrate do not overlap the orthographic projection of the gate electrode on the base substrate.

6. The display substrate according to claim 5, wherein the plurality of thin film transistors comprise a plurality of first thin film transistors in the display region;
the display substrate further comprises a plurality of gate lines each extending in a first direction and a plurality of data lines each extending in a second direction, wherein the data lines are in the first conductive layer; and
the plurality of gate lines and the plurality of data lines define a plurality of pixel units, each of the pixel units comprises the first thin film transistor and a corresponding pixel electrode, a part of the gate line also serves as a gate electrode of the first thin film transistor, a first electrode of the first thin film transistor is connected to the pixel electrode, and a second electrode of the first thin film transistor is connected to the data line.

7. The display substrate according to claim 6, wherein the gate electrode of the first thin film transistor and the light-shielding pattern are insulated from each other.

8. The display substrate according to claim 6, wherein an orthographic projection of an active pattern of the first thin film transistor on the base substrate is of an L-shaped pattern, the first connection part and the channel part each extend in the second direction, and the second connection part comprises a part extending in the first direction and a part extending in the second direction.

9. The display substrate according to claim 6, wherein the plurality of thin film transistors comprises a plurality of second thin film transistors in the peripheral region; and
a first electrode, a second electrode and a gate electrode of the second thin film transistor are all conductive patterns extending along the second direction.

10. The display substrate according to claim 9, wherein an orthographic projection of an active pattern of the second thin film transistor on the base substrate is of a rectangular pattern, and the first connection part, the channel part, and the second connection part are sequentially arranged along the first direction.

11. The display substrate according to claim 9, wherein the plurality of second thin film transistors comprises a plurality of first sub-transistors and a plurality of second sub-transistors,
wherein the light-shielding pattern and the gate electrode of the first sub-transistor are electrically connected; and
the light-shielding pattern and the gate electrode of the second sub-transistor are insulated from each other.

12. The display substrate according to claim 11, wherein
the first sub-transistor further comprises a first transfer electrode in the first conductive layer, and the light-shielding pattern and the gate electrode of the first sub-transistor are electrically connected through the first transfer electrode.

13. The display substrate according to claim 12, wherein the display substrate further comprises:
a buffer layer between the light-shielding pattern and the active pattern; and
an interlayer dielectric layer between the active pattern and the first conductive layer and on a side of the gate electrode away from the base substrate;
the first transfer electrode is connected to the gate electrode through a first via and is connected to the light-shielding pattern through a second via, wherein the first via is in the interlayer dielectric layer, and the second via penetrates through the interlayer dielectric layer and the buffer layer, and
an orthographic projection of the first via on the base substrate and an orthographic projection of the second via on the base substrate do not overlap the orthographic projection of the active pattern on the base substrate.

14. The display substrate according to claim 11, wherein
the first sub-transistor further comprises a second transfer electrode in a same layer as the pixel electrode, and the light-shielding pattern and the gate electrode of the first sub-transistor are electrically connected through the second transfer electrode.

15. The display substrate according to claim 14, wherein the display substrate further comprises:
a buffer layer between the light-shielding pattern and the active pattern;
an interlayer dielectric layer between the active pattern and the first conductive layer and on a side of the gate electrode away from the base substrate; and
a passivation layer between the first conductive layer and the pixel electrode;
wherein the second transfer electrode is connected to the gate electrode through a third via and is connected to the light-shielding pattern through a fourth via, wherein the third via penetrates through the interlayer dielectric layer and the passivation layer, and the fourth via penetrates through the interlayer dielectric layer, the passivation layer and the buffer layer, and
an orthographic projection of the third via on the base substrate and an orthographic projection of the fourth via on the base substrate do not overlap the orthographic projection of the active pattern on the base substrate.

16. The display substrate according to claim 11, wherein the peripheral region comprises a first peripheral sub-region, the first peripheral sub-region comprises a first region on a side of the display region in the second direction,
the display substrate further comprises a plurality of multiplexing circuits, each of the multiplexing circuits is electrically connected to a selection control signal line, a driving signal line provided by a source driver chip and n data lines, and is configured to provide a data signal output by the source driver chip to the n data lines under control of the selection control signal line; and
each of the multiplexing circuits comprises at least one second sub-transistor, a part of the selection control signal line also serves as a gate electrode of the second sub-transistor, a first electrode of the second sub-transistor is connected to the driving signal line, and a second electrode of the second sub-transistor is connected to the data line corresponding to the multiplexing circuit to which the second sub-transistor belongs.

17. The display substrate according to claim 16, wherein multiple ones of the plurality of the multiplexing circuits constitute one multiplexing unit, and
in a same multiplexing unit, first electrodes of different second sub-transistors corresponding to different multiplexing circuits are connected to a same driving signal line.

18. The display substrate according to claim 16, wherein the first peripheral sub-region further comprises a second region on a side of the display region away from the first region,
the display substrate further comprises an electrostatic discharge protection circuit in the second region, wherein the electrostatic discharge protection circuit is configured to discharge static electricity generated in the display substrate, and
the electrostatic discharge protection circuit comprises at least one second sub-transistor,
wherein the peripheral region further comprises a second peripheral sub-region, the second peripheral sub-region comprises a third region on a side of the second region away from the display region, and
the display substrate further comprises a touch detection circuit in the third region, wherein the touch detection circuit comprises at least one of the first sub-transistors,
wherein the second peripheral sub-region further comprises fourth regions on both sides of the display region in the first direction,
the display substrate further comprises a gate driver circuit configured to provide a scan signal to the gate lines row by row, and
the gate driver circuit comprises multiple ones of the first sub-transistors.

19-20. (canceled)

21. The display substrate according to claim 11, wherein width-to-length ratios of channel parts of the first thin film transistor and the first sub-transistor are each in a range from 5/5 to 60/5, and/or
a width-to-length ratio of a channel part of the second sub-transistor is in a range from 7.5/5 to 90/5.

22. (canceled)

23. A display panel, comprising the display substrate according to claim 1.
